(19) United States
(12) Patent Application Publication
(10) Pub. No.: US 2005/0158907 A1
(43) Pub. Date: Jul. 21, 2005

(54) Image sensor device and method of fabricating the same

(76) Inventors: Jhy-Jyi Sze, Tainan (TW); Min-Hua Tsai, Banciao City (TW); Tzung-Han Tan, Taipei City (TW); Hsin-Ping Wu, Yilan City (TW); Chia-Huei Lin, Shulin City (TW)

Correspondence Address: J C PATENTS, INC., 4 VENTURE, SUITE 250, IRVINE, CA, 92618, US

(21) Appl. No.: 10/893,674

(22) Filed: Jul. 15, 2004

Related U.S. Application Data
(62) Division of application No. 10/761,992, filed on Jan. 21, 2004.

(51) Int. Cl. H01L 21/00; H01L 31/0232

(52) U.S. Cl. 438/65; 257/432; 257/461; 438/48

(57) ABSTRACT

A method of fabricating an image sensor device is disclosed. In the method, a substrate having a plurality of trenches therein is provided. A first anti-reflective layer is formed on the surfaces of the trenches. An insulating layer is filled in the trenches for forming a plurality of shallow trench isolation regions. At least one photo sensitive region is formed within the substrate between neighboring shallow trench isolation regions. A second anti-reflective layer is formed at least covering the photo sensitive region. Because the first anti-reflective layer is formed on the surfaces of the trenches, and the second anti-reflective layer is formed on the photo sensitive region, the sensitivity of the image sensor device is improved.

### BACKGROUND OF THE INVENTION

1. Field of the Invention

The present invention relates to a structure of photodiode image sensor device and a method of fabricating the same, and more particularly to a structure of photodiode image sensor device and a method of fabricating the same that can improve sensitivity thereof.

2. Description of the Related Art

Photodiode image sensors are commonly used image sensor devices. A traditional photodiode image sensor comprises a reset transistor and a photo sensitive region composed of a diode. For example, in a diode composed of an N-type doped region and a P-type substrate, when a voltage is applied to the gate of the reset transistor, the photodiode image sensor operates, turning on the reset transistor, and charges the junction of the N/P diode to create a reverse bias and a depletion region within the NIP diode. When the voltage difference across the depletion region reaches a predetermined high level, the reset transistor is turned off. When light is exposed on the photo sensitive region of the N/P diode, electrons and holes generated therefrom are separated by the electrical field of the depletion region. Electrons move towards the N-type doped region, and the potential of the N-type doped region is reduced, and holes move towards P-type substrate.

A complementary metal-oxide-semiconductor image sensor has high quantum efficiency, low read noise, high dynamic range, and the characteristics of random access. Moreover, the process of fabricating complementary metal-oxide-semiconductor image sensors is completely compatible with that of fabricating complementary metal-oxide-semiconductor devices. Therefore, it is easy to integrate the complementary metal-oxide-semiconductor image sensors with other control circuits, A/D converters and digital signal processing circuits within a same chip for achieving the function of system on a chip (SOC). Therefore, the advance of the process of fabricating complementary metal-oxide-semiconductor image sensors can substantially reduce costs of fabricating the image sensors, reduce sizes of pixels and power consumption. Therefore, complementary metal-oxide-semiconductor image sensors have replaced charge coupled devices in the field of low-price application.

Generally, in order to improve the efficiency of incident light reaching the photo sensitive regions, and enhance sensitivity of the complementary metal-oxide-semiconductor image sensors, an anti-reflective layer is formed on the photo sensitive regions in the process for absorbing irradiation and preventing light reflection. Moreover, in order to shrink the sizes of devices, a shallow trench isolation structure has replaced a traditional local oxidation structure below 0.18 μm technologies.

FIGS. 1A-1B are a schematic cross-sectional process flow illustrating a method of fabricating an image sensor device of a prior art. For simplifying the illustration, some components and related descriptions are omitted in the subsequent process.

Referring to FIG. 1A, first a substrate 100 is provided, wherein shallow trench isolation regions 102 have been formed within the substrate 100. Then, the shallow trench isolation regions 102 are used as an implantation mask. A photo sensitive region 104 is formed within the substrate 100 by using an ion implantation and a thermal diffusion processes.

Next, referring to FIG. 1B, a silicon nitride layer or a silicon oxynitride layer is formed on the substrate 100 at least covering the photo sensitive region 104 by performing a chemical vapor deposition process, wherein the silicon nitride layer or silicon oxynitride layer functions as an anti-reflective layer 106.

However, the image sensor devices fabricated by the method mentioned above have some problems. Although the anti-reflective layer 106 is formed on the photo sensitive region 104, the efficiency of light exposure is not good at the bottoms and sidewalls of the shallow trench isolation regions 104 because of high reflection thereof. It means that the effective photo sensitive region is limited to the photo sensitive region 104 on the surface of the substrate 100. However, because of size shrinkage of devices, the area of the photo sensitive region 104 on the surface of the substrate 100 is also reduced. That will result in reduction of the effective photo sensitive region and the sensitivity of the image sensor device becomes worse.

In addition, the process of forming the shallow trench isolation regions 102 generates stress therein. The stress will create dislocations at the shallow trench isolation regions 102 and affect isolation performance. Therefore, the leakage current phenomenon occurs at the photo sensitive region 104. Moreover, the leakage-current issue will generate large dark currents in the image sensor devices, and result in the increase of read noises.

### SUMMARY OF THE INVENTION

Accordingly, one object of the present invention is to provide an image sensor device and a method of fabricating the same, which increase the area of the photo sensitive region of the image sensor device, and enhance the sensitivity of the image sensor device.

Another object of the present invention is to provide an image sensor device and a method of fabricating the same, which reduce the stress within the shallow trench isolation structure, and also reduce dark currents in the photo sensitive region of the image sensor device.

The present invention discloses a method of fabricating an image sensor device. In the method, a substrate having a plurality of trenches therein is provided. A first anti-reflective device is formed on the surfaces of the trenches. An insulating layer is filled in the trenches for forming a plurality of shallow trench isolation regions. At least one photo sensitive region is formed within the substrate between neighboring shallow trench isolation regions. A second anti-reflective layer is formed at least covering the photo sensitive region.

The present invention discloses an image sensor device. The device comprises a substrate, a first anti-reflective layer, an insulating layer, at least one photo sensitive region and a second anti-reflective layer. The substrate has a plurality of trenches. The first anti-reflective layer is located on the surfaces of the trenches. Additionally, the insulating layer is located on the first anti-reflective layer and completely fills the trenches, wherein a plurality of shallow trench isolation regions are composed of the trenches, the first anti-reflective layer and the insulating layer. Moreover, the photo sensitive region is within the substrate between the neighboring shallow trench isolation regions. The second anti-reflective layer is at least disposed on the photo sensitive region.

From the image sensor device and the method of fabricating the same mentioned above, not only does the image sensor device of the present invention include the second anti-reflective layer, but the first anti-reflective layer is formed on the bottoms and sidewalls of the shallow trench isolation regions. Therefore, the efficiency of light exposure is improved at the bottoms and sidewalls of the shallow trench isolation regions. It means that the area of the effective photo sensitive region increases and the sensitivity of the image sensor device is enhanced.

In addition, because the first anti-reflective layer is formed on the bottoms and sidewalls of the shallow trench isolation regions, the stress in the shallow trench isolation regions can be reduced. Therefore, dislocations within the shallow trench isolation regions can be reduced and do not affect isolation performance. Accordingly, leakage currents occurring at the dislocations within the photo sensitive region can be avoided, and dark currents resulting from the photo sensitive region of the image sensor device are also reduced.

In order to make the aforementioned and other objects, features and advantages of the present invention understandable, a preferred embodiment accompanied with figures is described in detail hereinafter.

### BRIEF DESCRIPTION OF THE DRAWINGS

FIGS. 1A-1B are a schematic cross-sectional process flow illustrating a method of fabricating a conventional image sensor device.

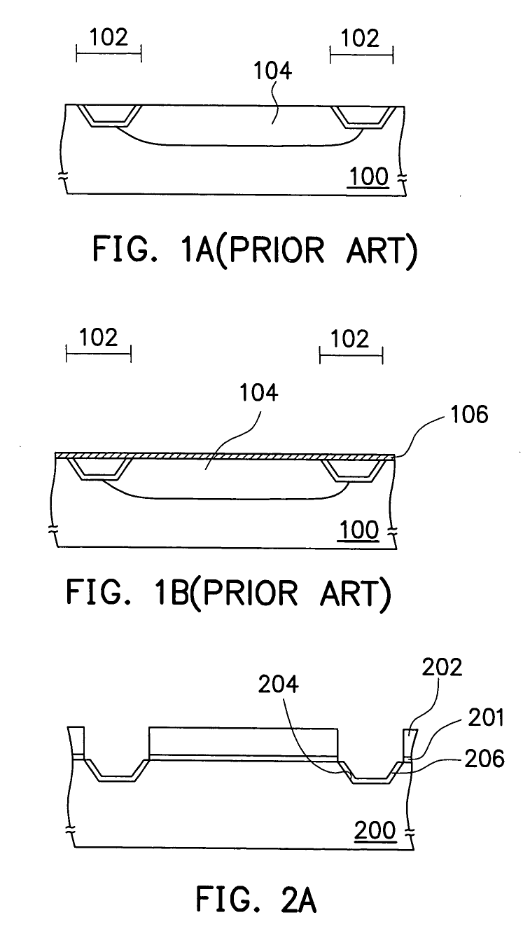

FIGS. 2A-2D are a schematic cross-sectional process flow illustrating a preferred embodiment of fabricating an image sensor device in accordance with the present invention.

### DESCRIPTION OF SOME EMBODIMENTS

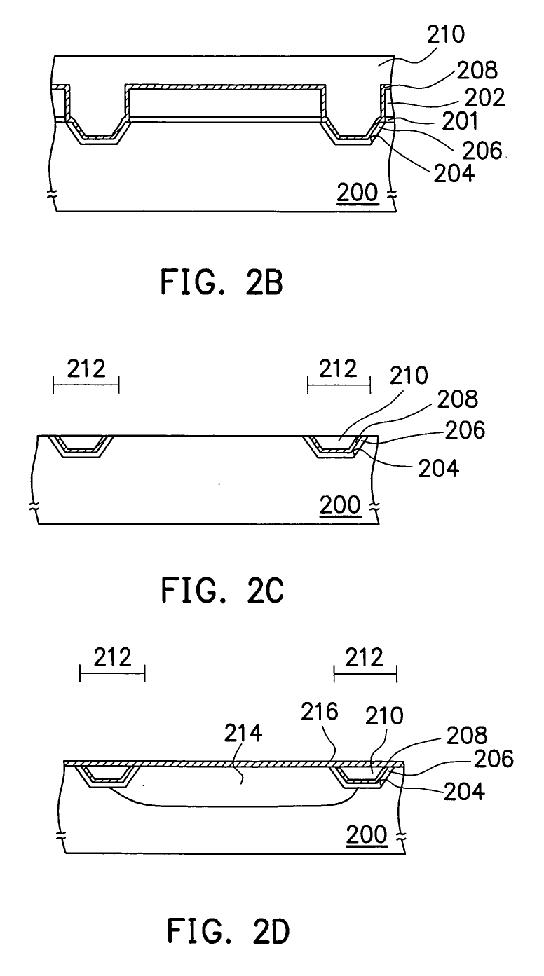

FIGS. 2A-2D are a schematic cross-sectional process flow illustrating a preferred embodiment of fabricating an image sensor device in accordance with the present invention. For simplifying the illustration, some components and related descriptions are omitted in the subsequent process.

Referring to FIG. 2A, a substrate 200 having a patterned pad oxide layer 201, a patterned mask layer 202, and trenches 204 thereon is provided. The material of the pad oxide layer 201 is, for example, silicon oxide, and the material of the mask layer 202 is, for example, silicon nitride. The above mentioned substrate 200 can be formed, for example, by sequentially forming the pad oxide 201 and the mask layer 202, then patterning the mask layer 202, the pad oxide 201 and the substrate 200 for forming trenches 204.

Next, referring to FIG. 2A, a liner layer 206 is formed on the surfaces of the trenches 204 for enhancing the adhesion between the surface of the substrate 200 and the subsequent anti-reflective layer (not shown). The material of the liner layer 206 is, for example, silicon oxide and formed by a thermal oxidation method.

Next, referring to FIG. 2B, an anti-reflective layer 208 is formed on the mask layer 202 and the surfaces of the trenches 204, wherein the material of the anti-reflective layer 208 is, for example, silicon oxide or silicon oxynitride. In addition, the method of forming the anti-reflective layer 208 is, for example, a chemical vapor deposition (CVD) process, wherein if the anti-reflective layer 208 is silicon nitride, the reaction gases are, for example, SiH₂Cl₂ and NH₃; and if the anti-reflective layer 208 is silicon oxynitride, the reaction gases are, for example, SiH₄ and NH₃.

It should be noted that because the anti-reflective layer 208 is formed on the surfaces of the trenches 204, the light reflection thereat can be substantially reduced which can affect the sensitivity of image sensor devices during sensing image.

Next, referring to FIG. 2B, an insulating layer 210 is filled in the trenches 204, wherein the material of the insulating layer 210 is, for example, silicon oxide.

Then, preferring to FIG. 2C, a planarization process is performed for removing portions of the anti-reflective layer 208 and the insulating layer 210 that are located outside the trenches 204. Then, the patterned pad oxide layer 201 and mask layer 202 are removed to form a plurality of shallow trench isolation regions 212. The planarization process is, for example, a chemical mechanical polish process.

In addition, the shallow trench isolation regions 212 divide the substrate 200 into transistor active regions (not shown) and photodiode sensitive regions. Because the subsequent process of forming the transistor active regions is well known to one of ordinary skill in the art, and therefore detail descriptions are omitted. The process related to forming photodiode sensitive regions is described hereinafter.

Next, referring to FIG. 2D, a photo sensitive region 214 is formed within the substrate 200 between neighboring shallow trench isolation regions 212, wherein the method of forming the photo sensitive region 214, for example, comprises performing ion implantation using the shallow trench isolation regions 212 as an implantation mask, and then performing thermal diffusion processes. Moreover, the implanted region has different type of dopants than that of the substrate 200 for forming N/P diode junction of the image sensor device. It should be noted that the photo sensitive region 214 can be, for example, simultaneously formed with the source/drain (not shown) of transistors of the transistor active regions.

Next, referring to FIG. 2D, an anti-reflective layer 216 is formed at least covering the photo sensitive region 214, and thus the process of fabricating the image sensor device is completed. The material of anti-reflective layer 216 is, for example, silicon nitride or silicon oxynitride. In addition, the method of forming the anti-reflective layer 216 is, for example, a chemical vapor deposition process, wherein if the anti-reflective layer 216 is silicon nitride, the reaction gases are, for example, SiH₂Cl₂ and NH₃; in addition, if the anti-reflective layer 216 is silicon oxynitride, the reaction gases are, for example, SiH₄ and NH₃.

Referring to FIG. 2D, the effective photo sensitive region of the image sensor device of the present invention comprises the photo sensitive region 214 formed on the surface of the substrate 200 and the bottoms and sidewalls of the shallow trenches isolation regions 212 adjacent thereto. Therefore, the image sensor device of the present invention has a larger effective photo sensitive region and has higher sensitivity.

The structure of the image sensor device is described hereinafter. Referring to FIG. 2D, the image sensor device comprises the substrate 200, the anti-reflective layers 208 and 216, the insulating layer 210 and at least a photo sensitive region 214.

The substrate 200 has a plurality of trenches 204. In addition, the anti-reflective layer 208 is on the surfaces of the trenches 204, wherein the material of the anti-reflective layer 208 is, for example, silicon nitride or silicon oxynitride. In addition, because the anti-reflective layer 208 is formed on the surfaces of the trenches 204, the light reflection thereat can be substantially reduced which can affect the sensitivity of image sensor devices during sensing image.

In addition, the insulating layer 210 is on the anti-reflective layer 208 and completely fills the trenches 204, wherein the material of the insulating layer 210 is, for example, silicon oxide. Also, the plurality of shallow trench isolation regions 212 is composed of the trenches 204, the anti-reflective layer 208 and the insulating layer 210.

Additionally, the photo sensitive region 214 is formed within the substrate 200 between neighboring shallow trench isolation regions 212, wherein the photo sensitive region 214 is a doped region having different type of dopant than that of the substrate 200, forming N/P diode junction of the image sensor device.

In addition, the anti-reflective layer 216 at least covers the photo sensitive region 214, wherein the material of anti-reflective layer 216 is, for example, silicon nitride or silicon oxynitride. Moreover, because the anti-reflective layer 216 is disposed on the surface of the photo sensitive region 214, the light reflection thereat can be substantially reduced which can affect the sensitivity of image sensor devices during sensing image.

Additionally, the liner layer 206 is between the surfaces of the shallow trenches and the anti-reflective layer 208 for enhancing the adhesion between the surface of the substrate 200 and the anti-reflective layer 208, wherein the material of the liner layer 206 is, for example, silicon oxide.

In order to prove the present invention feasible, measurements of leakage currents and photo-electrical characteristics are performed on image sensor of the present invention device and the prior art image sensor. Table 1 shows the results of the measurements of leakage currents of the image sensor device of the present invention and the prior art image sensor. Table 2 shows the results of measurements concerning efficiency of photoelectric effect of the image sensor device of the present invention and the prior art image sensor.

TABLE 1

| | The leakage current of the | |
|---|---|---|
| | present invention image | The leakage current of the |
| Voltage (V) | sensor device | prior art image sensor device |
| 3.3 | 2.766 | 5.601 |
| 2.5 | 2.030 | 4.223 |
| 2.0 | 1.633 | 3.440 |
| 1.5 | 1.270 | 2.686 |

Referring to Table 1, the leakage currents of the image sensor device of the present invention are smaller than those of the prior art image sensor device. This is because, the anti-reflective layer formed at the bottoms and sidewalls of the shallow trench isolation regions enhances the sensitivity of the image sensor device and also reduces the leakage currents of the image sensor device.

TABLE 2

| | Efficiency of | Efficiency of |
|---|---|---|
| | photoelectric effect of | photoelectric effect of |
| | the present invention | the prior art image |
| Voltage (V) | image sensor device | sensor device |
| 2.5 | 9.01E−10 | 5.46E−10 |

Referring to Table 2, when the same voltage is applied to the image sensor of the present invention and the image sensor of the prior art, the efficiency of of photoelectric effect of the image sensor device of the present invention is about 1.651 times than thatof the prior art image sensor device. It means that the present invention having the anti-reflective layer at the bottoms and sidewalls of the shallow trench isolation regions increases the effective photo sensitive region of the image sensor device and improve the sensitivity thereof.

The image sensor of the present invention has at least the following advantages.

Not only does the image sensor device of the present invention include the anti-reflective layer 216, but also the anti-reflective layer 208 is formed on the bottoms and sidewalls of the shallow trench isolation regions 212. The anti-reflective layer 208 can resolve the issue of light reflection at the bottoms and sidewalls of the shallow trench isolation regions 212 when incident light passes through the shallow trench isolation regions 212. Therefore, the image sensor device of the present invention reduces light reflection at the bottoms and sidewalls of the shallow trench isolation regions 212. It means that the area of the effective photo sensitive region of the image sensor device increases, and currents generated at the photo sensitive region 214 is enhanced.

In addition, because the anti-reflective layer 208 is formed on the bottoms and sidewalls of the shallow trench isolation regions 212, the stress in the shallow trench isolation regions 212 can be reduced. Therefore, dislocations within the shallow trench isolation regions 212 can be reduced and do not affect isolation performance. Accordingly, leakage currents generated from the dislocations within the photo sensitive region 214 can be avoided, and dark currents resulting from the photo sensitive region 214 of the image sensor device are also reduced.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1-7. (canceled)

8. A photo imagine sensor device, comprising:
a substrate, having a plurality of trenches formed thereon;
a first anti-reflective layer, formed on the surfaces of the trenches;
an insulating layer, formed on the first anti-reflective layer, filing the trenches,
wherein a plurality of shallow trench isolation regions are composed of the trenches, the first anti-reflective layer and the insulating layer;
at least one photo sensitive region, formed within the substrate between two neighboring shallow trench isolation regions; and
a second anti-reflective layer, formed on the photo sensitive region.

9. The photo imagine sensor device of claim 8, wherein the material of the first anti-reflective layer is selected from a group consisting of silicon nitride or silicon oxynitride.

10. The photo imagine sensor device of claim 8, wherein the material of the second anti-reflective layer is selected from a group consisting of silicon nitride or silicon oxynitride.

11. The photo imagine sensor device of claim 8, further comprising a liner layer between the surfaces of the trenches and the first anti-reflective layer.
